(19) United States
(12) Patent Application Publication
(10) Pub. No.: US 2026/0305382 A1
(43) Pub. Date: Oct. 1, 2026

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/478,272

(22) PCT Filed: Apr. 17, 2024
(86) PCT No.: PCT/JP2024/015219

§ 371 Date: Oct. 24, 2025

(30) Foreign Application Priority Data
Apr. 28, 2023 (JP) 2023-074805

(51) Int. Cl. H10W 70/40

(52) U.S. Cl. CPC H10W 70/435

(57) ABSTRACT

An electronic module includes: a first semiconductor element including first and second electrodes, a second semiconductor element including third and fourth electrodes, an intermediate point power terminal having a flat plate shape that is connected to the other electrode out of the first electrode and the second electrode and the other electrode out of the third electrode and the fourth electrode, and an internal connection frame having a flat shape that connects the other electrode out of the first electrode and the second electrode and the other electrode out of the third electrode and the fourth electrode to each other, and has an elongated hole provided for fitting the intermediate point power terminal therein by press fitting. The intermediate point power terminal is erected in a perpendicular direction by being fitted into the elongated hole of the internal connection frame by press fitting.

### RELATED APPLICATIONS

This application is a National Phase of International Application No. PCT/JP 2024/015219 filed Apr. 17, 2024, which claims priority based on Patent Application 2023-074805 filed in Japan on Apr. 28, 2023, and the entire contents of the application are incorporated herein by reference.

### TECHNICAL FIELD

The present invention relates to an electronic module.

### BACKGROUND ART

Conventionally, there has been known an electric module 500 having a half bridge structure (see Patent Literature 1, for example). As the above-mentioned electronic module, for example, there exists an electronic module that has the following configuration. For example, the electronic module 500 illustrated in FIG. 14 includes a first transistor (semiconductor element) 730 on a high side, a second transistor (semiconductor element) 740 on a low side, a first power terminal 630 connected to a first drain electrode (not illustrated in the drawing) of the first transistor 730, a second power terminal 640 connected to a second source electrode (not illustrated in the drawing) of the second transistor 740, and an intermediate point power terminal 660 connected to a first source electrode (not illustrated in the drawing) of the first transistor 730 and a second drain electrode (not illustrated in the drawing) of the second transistor 740, thus forming the half bridge structure.

### PRIOR ART LITERATURE

### Patent Literature

[Patent literature 1] WIPO 2013/146212

### SUMMARY OF INVENTION

### Technical Problem

However, in a case where, to reduce inductance and wiring resistance, the first power terminal 630, the second power terminal 640 and the intermediate point power terminal 660 are formed of planar terminals, and a current is taken out to the outside by applying the cell nut structure to these three terminals, it is necessary to secure connection regions between the external connection member and the intermediate point power terminal 660. Accordingly, it is difficult to reduce a planar area of the intermediate point power terminal 660 that is positioned between the first transistor 730 and the second transistor 740 and hence, it is difficult to narrow a distance between the first transistor 730 and the second transistor 740. As a result, a package becomes large-sized and, at the same time, a wiring length is increased. Attributed to these factors, there arises a drawback that inductance and wiring resistance are increased. With respect to the above-mentioned drawback, substantially the same drawback arises in a case where as the semiconductor chip, in place of the transistor, a three-electrode semiconductor chip (a thyristor, for example) or a two-electrode semiconductor chip (a diode, for example) other than the transistor is used.

The present invention has been made in view of the above-mentioned drawbacks, and it is an object of the present invention to provide an electronic module capable of reducing inductance and wiring resistance while securing a connection region with an external connection member and an intermediate point power terminal in an electronic module that includes two semiconductor chips.

### Solution to Problem

An electronic module according to the present invention includes: a first semiconductor element that includes two electrodes consisting of a first electrode and a second electrode; a second semiconductor element that includes two electrodes consisting of a third electrode and a fourth electrode; a first power terminal having a flat plate shape that is connected to either one electrode out of the first electrode and the second electrode; a second power terminal having a flat plate shape that is connected to either one electrode out of a third electrode and a fourth electrode; and an intermediate point power terminal having a flat plate shape that is connected to an other electrode out of the first electrode and the second electrode and the other electrode out of the third electrode and the fourth electrode, wherein the electronic module further comprises an internal connection frame having a flat plate shape that connects the other electrode out of the first electrode and the second electrode and the other electrode out of the third electrode and the fourth electrode to each other, the internal connection frame having an elongated hole provided for fitting the intermediate point power terminal by press fitting, and the intermediate point power terminal is erected in a perpendicular direction by being fitted into the elongated hole of the internal connection frame.

### Advantageous Effects of the Present Invention

According to the electronic module of the present invention, the intermediate point power terminal is fitted into the elongated hole of the above-mentioned internal connection frame and is erected in the perpendicular direction and hence, it is possible to secure a connection region between an outer connection member and the intermediate point power terminal 660 with certainty.

Further, a distance between a place where the first semiconductor element is disposed and a place where the second semiconductor element is disposed can be narrowed. Accordingly, a package can be made small and a wiring length can be made short and hence, inductance and wiring resistance can be reduced.

### BRIEF DESCRIPTION OF DRAWINGS

FIG. 1 is a perspective view illustrating an external appearance of an electronic module 100 according to a first embodiment.

FIG. 2 is a side view of the electronic module 100 according to the first embodiment.

FIG. 3 is a view illustrating a shape of an elongated hole.

FIG. 4 is a partially exploded perspective view illustrating the internal structure of the electronic module 100 according to the first embodiment.

FIG. 5A and FIG. 5B are views illustrating the electronic module 100 according to the first embodiment. FIG. 5A is a plan view of the electronic module 100 according to the first embodiment. FIG. 5B is a view illustrating a cross-sectional structure in the vicinity of two semiconductor elements that constitute the electronic module 100 illustrated in FIG. 5A.

FIG. 6A to FIG. 6D are views illustrating a connection mode of two semiconductor elements. FIG. 6A to FIG. 6C are views illustrating examples of the connection mode in a case where two semiconductor elements are formed of a diode, and FIG. 6D is a view illustrating an example of the connection mode in a case where only one of two semiconductor elements is formed of a diode.

FIG. 7 is a perspective view illustrating an external appearance of an electronic module 300 according to a second embodiment.

FIG. 8 is a partially exploded perspective view illustrating an internal structure of the electronic module 300 according to the second embodiment.

FIG. 9A to FIG. 9D are views illustrating a connection mode of two semiconductor elements. FIG. 9A to FIG. 9D are views illustrating examples of the connection mode in a case where two semiconductor elements are formed of a transistor.

FIG. 10A to FIG. 10C are views is a view illustrating the electronic module 300 according to the second embodiment. FIG. 10A to FIG. 10C are views illustrating one example of the cross-sectional structure in the vicinity of two semiconductor elements that constitutes the electronic module 300 according to the second embodiment.

FIG. 11 is a perspective view illustrating an external appearance of an electronic module 400 according to a third embodiment.

FIG. 12A to FIG. 12D are views illustrating the electronic module 400 according to the third embodiment. FIG. 12A to FIG. 12D are views illustrating one example of the cross-sectional structure in the vicinity of two semiconductor elements that constitute the electronic module 400 according to the third embodiment.

FIG. 13 is a view illustrating one example of a connection mode where the number of semiconductor elements that constitute the electronic module 100 is four.

FIG. 14 is a view for describing an electronic module according to the prior art.

### DESCRIPTION OF EMBODIMENTS

### First Embodiment

Hereinafter, an electronic module according to a first embodiment of the present invention is described by taking a diode module as an example of the electronic module. The embodiment described hereinafter is not intended to limit the invention called for in claims. Further, it is not always the case that various elements and all combinations of these elements described in the embodiment are indispensable for the present invention.

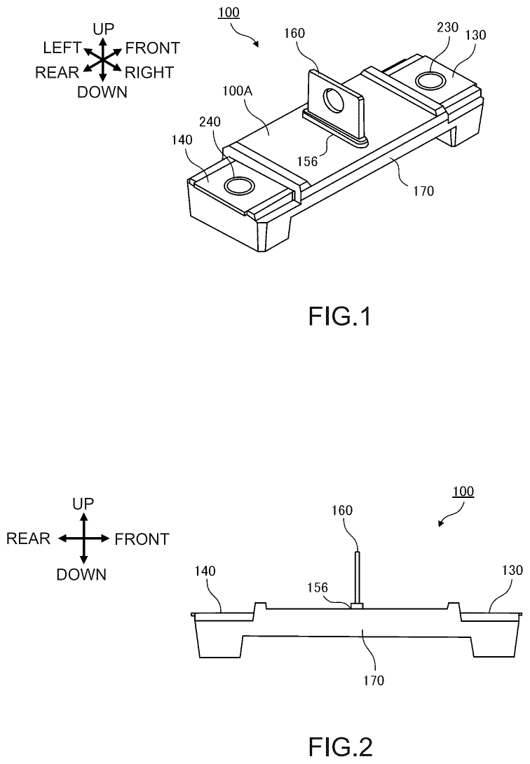

In the description made hereinafter, as illustrated in FIG. 1 and FIG. 2, the description is made by setting a longitudinal direction of the electronic module 100 as a front-rear direction, and a lateral direction as a left-and-right direction. Further, the description is made by setting a height direction of the electronic module 100 as an up-down direction. The terms “front”, “rear”, “left”, “right”, “up” and “down” in the description made hereinafter are used for the sake of convenience of the description, and do not specify the direction that the electronic module 100 is mounted when the electronic module 100 is used.

As illustrated in FIG. 1 to FIG. 4, the electronic module 100 is formed in an approximately rectangular parallelepiped body shape being elongated in the front-rear direction and being flat in the up-down direction. The electronic module 100 includes an insulation board 112, a first conductive body 114, a second conductive body 116, a first semiconductor element 118, a second semiconductor element 120, a first power terminal 130, a second power terminal 140, an internal connection frame 152, a third power terminal 160, and a sealing resin 170.

The insulation board 112 is a direct copper bonding board (a DCB board) where a metal plate for heat dissipation is formed on a lower surface (a back surface) of an insulation board made of ceramic, and the first conductive body 114 and the second conductive body 116 are formed. The insulation board 112 may be a printed circuit board or the like. It is preferred that the insulation board 112 is formed in a rectangular flat plate shape, and is disposed at a center portion of the electronic module 100 in a front-and rear direction that is a longitudinal direction.

The first conductive body 114 and the second conductive body 116 are conductive bodies formed on the insulation board 112. As illustrated in FIG. 4, the first semiconductor element 118 is disposed on the first conductive body 114, and the second semiconductor element 120 is disposed on the second conductive body 116. The first semiconductor element 118 and the second semiconductor element 120 are respectively formed of a diode. The first semiconductor element 118 has a cathode electrode (not illustrated in the drawing) that is formed on one-side surface (a surface (lower surface) on an insulation board 112 side), and an anode electrode 118A that is formed on the other-side surface (surface (upper surface) on a side opposite to the insulation board 112). The second semiconductor element 120 has a cathode electrode (not illustrated in the drawing) formed on one-side surface (surface (lower surface) on the insulation board 112 side), and an anode electrode 120A formed on the other-side surface (surface (upper surface) on a side opposite to the insulation board 112). The cathode electrodes of the first semiconductor element 118 and the second semiconductor element 120 are bonded to the first conductive body 114 and the second conductive body 116 by a conductive bonding material respectively.

As illustrated in FIG. 1, FIG. 2 and FIG. 4, the first power terminal 130 and the second power terminal 140 are disposed on a front side of the electronic module 100 in the longitudinal direction. The first power terminal 130 and the second power terminal 140 are each formed of a flat plate member (for example, a copper plate) 132A and a flat plate member (for example, a copper plate) 142A having electrically conductive property respectively. The first power terminal 130 is constituted of the flat plate member (for example, a copper plate) 132A having electrically conductive property, and the second power terminal 140 is constituted of a flat plate member (for example, a copper plate) 142A having electrically conductive property.

As illustrated in FIG. 1, FIG. 2 and FIG. 4, the third power terminal 160 is formed of a flat plate member (for example, a copper plate) 160A having electrically conductive property. The third power terminal 160 is disposed such that a longitudinal direction becomes a plate thickness direction, and is formed in an elongated shape such that an up-down direction becomes a longitudinal direction. The third power terminal 160 is disposed on an upper side of the sealing resin 170, and has a portion that is exposed from the sealing resin 170 and a portion covered by the sealing resin 170.

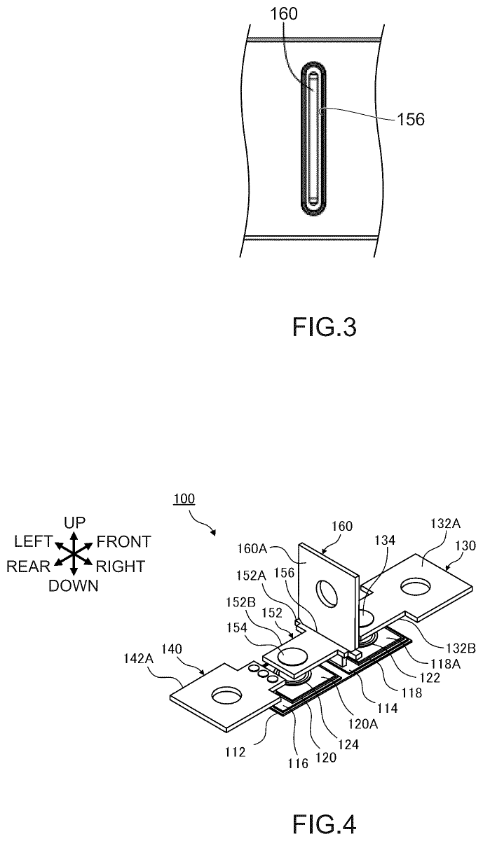

As illustrated in FIG. 3, an elongated hole 156 is formed in the internal connection frame 152. A width size of the third power terminal 160 in a left-right direction is set slightly smaller than a longitudinal direction width of the elongated hole 156. As viewed in a plan view, the elongated hole 156 formed in the internal connection frame 152 extends along a direction orthogonal to a line that connects the first semiconductor element 118 and the second semiconductor element 120 in a region that is sandwiched by the anode electrode of the first semiconductor element 118 and the cathode electrode of the second semiconductor element 120.

A lower side portion of the third power terminal 160 is fitted into the elongated hole 156 of the internal connection frame 152 by press fitting. The lower side portion of the third power terminal 160 is partially in contact with the internal connection frame 152 in the elongated hole 156, and is electrically connected to the internal connection frame 152. A lower end surface of the third power terminal 160 is connected to predetermined electrodes of the first semiconductor element 118 and the second semiconductor element 120 by a conductive bonding material.

In the above-mentioned embodiment, the case where the semiconductor element is formed of a diode module is described. However, in a case where the semiconductor element is a MOS transistor or an insulation-gate-type bipolar transistor (IGBT), the semiconductor module is configured such that a signal terminal (not illustrated in the drawing) that functions as a control terminal protrudes above the sealing resin 170 from a gate electrode that constitutes the MOS transistor or the IGBT, and the signal terminal is connected to an external connection member (not illustrated in the drawing).

In the first embodiment, the first semiconductor element 118 and the second semiconductor element 120 are formed of a diode respectively. The semiconductor element may be, besides a diode, other types of semiconductor element such as a power metal-oxide-semiconductor field-effect transistor (MOSFET), a thyristor, or an electronic element described later. Further, as a material of the semiconductor element, a raw material such as silicon, SiC, GaN can be used. Specific examples in cases where the semiconductor element is a MOS transistor or an insulation-gate-type bipolar transistor (IGBT) are described later.

### (Equivalent Circuit and Cross-Sectional Structure of Semiconductor Element in Diode Module)

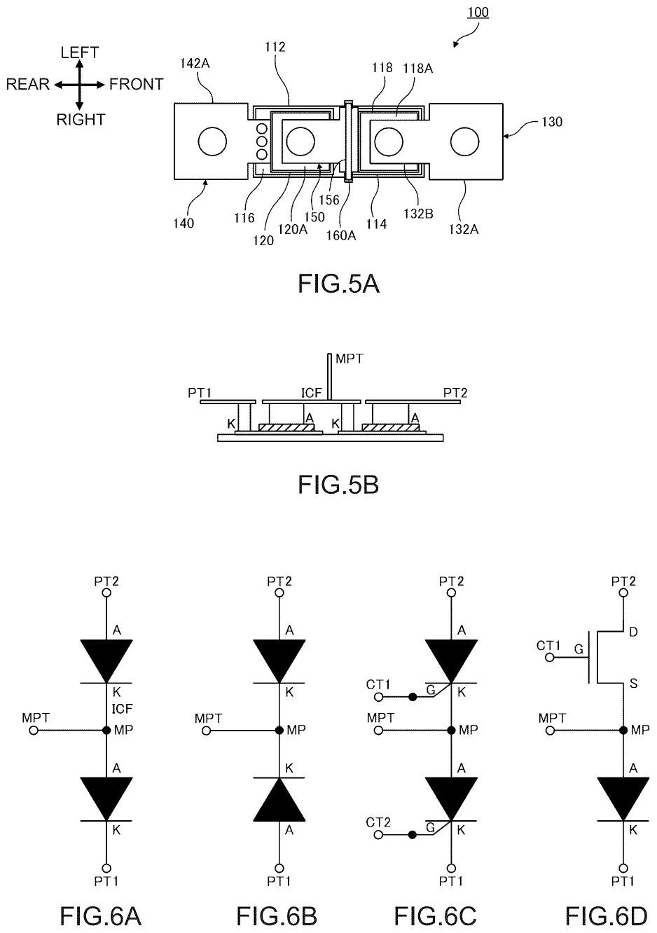

Hereinafter, the equivalent circuit and the cross-sectional structure of the semiconductor element in a case where the electronic module is a diode module are described with reference to FIG. 5B, FIG. 6A to FIG. 6C. FIG. 6A to FIG. 6C are views respectively illustrating equivalent circuit variations 1 to 3 of the electronic module 100 (diode module), and FIG. 5B is a view illustrating the cross-sectional structure of the diode module corresponding to the equivalent circuit illustrated in FIG. 6A.

### Connection Variations

As illustrated in FIG. 5A, FIG. 5B and FIG. 6A, using the first semiconductor element 118 as an upper-side diode illustrated in FIG. 6A and the second semiconductor element 120 as a lower-side diode illustrated in FIG. 6A, the first semiconductor element 118 and the second semiconductor element 120 are connected to each other via a connection point (hereinafter, referred to as “node”) MP between an internal connection frame ICF (corresponding to 150 in FIG. 5A) and an intermediate point power terminal MPT (corresponding to 160 in FIG. 4) in series. Further, an anode electrode A (corresponding to 118A in FIG. 4) of the upper-side diode is connected to a power terminal second power terminal PT2 (corresponding to 130 in FIG. 4), a cathode electrode K of an upper-side diode is connected to an anode electrode A (corresponding to 120A in FIG. 4) of a lower-side diode, and a cathode electrode K of the lower side diode is connected to a first power terminal PT1 (corresponding to 140 in FIG. 4).

As a modification, polarities of the lower-side diode are reversed, and the cathode electrode K of the upper-side diode may be connected to the cathode electrode K of the lower-side diode (see FIG. 6B). Further, as another modification, a thyristor may be used in place of the diode (see FIG. 6C). As another modification, although it may not be referred to as a pure diode module, one of two diodes (for example, the upper-side diode) may be replaced with a MOS transistor (see FIG. 6D). Control terminal CT1, CT2 illustrated in FIG. 6C and FIG. 6D are input/output nodes of control signals.

### Advantageous Effects Acquired by First Embodiment

The electronic module 100 according to the first embodiment includes: the first semiconductor element 118 that includes two electrodes consisting of the first electrode and the second electrode; the second semiconductor element 120 that includes two electrodes consisting of the third electrode and the fourth electrode; the first power terminal 130 having a flat plate shape that is connected to either one electrode out of the first electrode and the second electrode; the second power terminal 140 having a flat plate shape that is connected to either one electrode out of the third electrode and the fourth electrode; and the intermediate point power terminal (the third power terminal 160) having a flat plate shape that is connected to the other electrode out of the first electrode and the second electrode and the other electrode out of the third electrode and the fourth electrode. The electronic module 100 further includes the internal connection frame 152 having a flat plate shape that connects the other electrode out of the first electrode and the second electrode and the other electrode out of the third electrode and the fourth electrode to each other. The internal connection frame 152 has the elongated hole 156 provided for fitting the intermediate point power terminal (the third power terminal 160) by press fitting. The intermediate point power terminal (the third power terminal 160) is erected in a perpendicular direction by being fitted into the elongated hole 156 of the internal connection frame 152 by press fitting.

According to the configuration of the above-mentioned first embodiment, in the electronic module having two semiconductor elements, a contact area of the intermediate point power terminals of two semiconductor elements with the internal connection frame 152 can be made small and, at the same time, a package can be made small and a wiring length can be made short. Accordingly, it is possible to provide an electronic module where inductance and wiring resistance are reduced.

Further, as viewed in a plan view, the elongated hole 156 extends along the direction orthogonal to the line that connects the first semiconductor element 118 and the second semiconductor element 120 to each other in the region sandwiched by the other electrode out of the first electrode and the second electrode of the first semiconductor element 118 and the other electrode out of the third electrode and the fourth electrode of the second semiconductor element 120. Accordingly, by extending the elongated hole 156 along the direction orthogonal to the line that connects two semiconductor elements to each other, a space can be ensured in a region in the longitudinal direction of the internal connection frame 152 that constitutes the electronic module 100 and hence, the degree of freedom in packaging (designing of a package) and designing of wiring is enhanced.

Further, it is preferred that the first power terminal 130, the second power terminal 140 and the internal connection frame 152 are derived from the same lead frame. That is, with such a configuration, compared to a case where the first power terminal 130 and the second power terminal 140 are connected striding over a plurality of lead frames, wiring lengths of connection wirings relating to the first power terminal 130, the second power terminal 140 and the internal connection frame 152 can be made short. Accordingly, it is possible to provide the electronic module where inductance and wiring resistance can be reduced.

### Second Embodiment

An electronic module 300 according to the second embodiment basically has substantially the same configuration as the electronic module 100 according to the first embodiment. However, the electronic module 300 according to the second embodiment differs from the electronic module 100 according to the first embodiment with respect to a point that a transistor is used in place of a diode as a semiconductor element.

### Second Embodiment

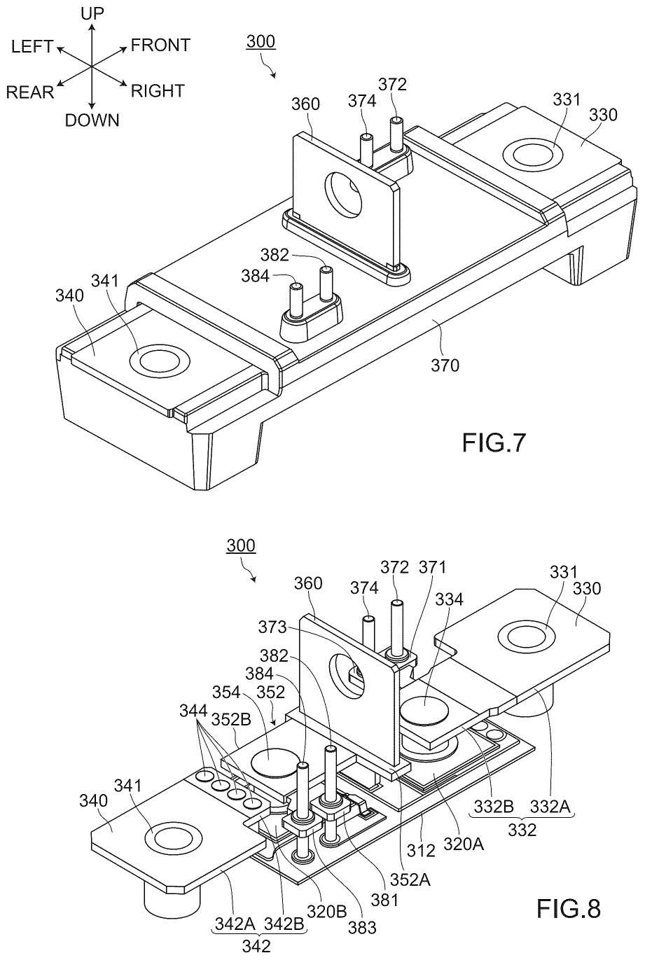

As illustrated in FIG. 7 and FIG. 8, the electronic module 300 according to the second embodiment is elongated in the front-rear direction, and is formed in an approximately rectangular parallelepiped body shape that is flat in the up-down direction. The electronic module 300 includes a semiconductor element 320, a first power terminal 330, a second power terminal 340, a third power terminal 360, a first connection frame (internal connection frame) 332B, a second connection frame 342B, and a sealing resin 170.

The electronic module 300 includes two semiconductor elements 320A, 320B. As the semiconductor element 320A, 320B, for example, a power metal-oxide-semiconductor field-effect transistor (MOSFET) can be used. The semiconductor element 320A, 320B may be disposed on one surface of an insulation board 312. The semiconductor element 320A, 320B includes electrodes (not illustrated in the drawing) that are formed on one surface or both surfaces of the semiconductor board.

The insulation board 312 is a ceramic board that is a portion of a direct copper bonding board (a DCB board) where a metal plate for heat dissipation is formed on a lower surface (back surface) of the ceramic board. For example, two semiconductor elements 320 are formed on one surface of the insulation board 312, and metal for heat dissipation is formed on the other surface of the insulation board 312. The insulation board 312 may be a printed circuit board or the like. The insulation board 312 is formed in a rectangular planner shape, and is disposed at a center portion of the electronic module 300 in a front-rear direction that is a longitudinal direction.

As illustrated in FIG. 7, the first power terminal 330 is disposed on a front side of the electronic module 300 in the front-rear direction. The first power terminal 330 is constituted of a flat plate member having electrically conductive property, for example, a plate member 332A made of copper and formed in a flat plate shape. The first power terminal 330 has a through hole 331 that penetrates the first power terminal 330 in the up-down direction. The through hole 331 has, for example, a circular shape as viewed in the up-down direction.

A first connection frame 332b is electrically connected with the first power terminal 330. The first connection frame 332B is embedded in the sealing resin 370. In the electronic module 300, the first connection frame 332B is integrally formed with the first power terminal 330 using the same plate member 332. That is, a portion of the plate member 332 that is embedded in the sealing resin 370 corresponds to the first connection frame 332B.

The first connection frame 332B has a through hole (symbol being omitted) that vertically penetrates the first connection frame 332B. The through hole is formed in a circular shape as viewed in the up-down direction. An upper end portion of an internal connection terminal 334 engages with the through hole by fitting engagement. The first connection frame 332B and an electrode of the semiconductor element 320A are connected with each other by the internal connection terminal 334. The internal connection terminal 334 is fixed to the first connection frame 332B by press fitting, for example. The shape of the through hole 341 is not limited to a circular shape, and may be a polygonal shape such as a hexagonal shape.

As illustrated in FIG. 8, the second power terminal 340 is disposed on a rear side of the electronic module 300 in the front-rear direction. The second power terminal 340 is constituted of a plate member 342A formed of a flat plate member having electrically conductive property, for example, a copper plate. The second power terminal 340 has a through hole 341 that penetrates the second power terminal 340 in the up-down direction. The through hole 341 has, for example, a circular shape as viewed in the up-down direction.

The second connection frame 342b is electrically connected with the second power terminal 340. The second connection frame 342B is embedded in the sealing resin 370.

In the electronic module 300, the second connection frame 342B is integrally formed using the same plate member 342 as the second power terminal 340. That is, a portion of the plate member 342 that is embedded in the sealing resin 370 corresponds to the second connection frame 342B.

The second connection frame 342B has four through holes (symbols being omitted) that penetrate the second connection frame 342B in the up-down direction. The through holes are formed in a circular shape as viewed in the up-down direction. An upper end portion of an internal connection electrode 344 engages with each of four through holes by fitting engagement. The second connection frame 342B and electrodes (not illustrated in the drawing) of the semiconductor element 320B are connected with each other by four internal connection electrodes 344. The internal connection electrodes 344 are fixed to the second connection frame 342B by press fitting, for example. The number of the above-mentioned through holes and the number of the above-mentioned internal connection electrodes 344 can be respectively set to an arbitrary number of one or more without being limited to four provided that the flow of required electricity is allowed.

The electronic module 300 includes a third power terminal 360. As illustrated in FIG. 8, the third power terminal 360 is formed of a flat plate member having electrically conductive property, for example, a copper plate. The third power terminal 360 is arranged such that a plate thickness direction is the front-rear direction, and is formed in an elongated shape with the upper-down direction set as the longitudinal direction. The third power terminal 360 has: a portion that is disposed on an upper side of the sealing resin 370 and is exposed from the sealing resin 370; and a portion covered by the sealing resin 370.

The electronic module 300 includes an internal connection frame 352. The internal connection frame 352 is electrically connected with the third power terminal 360. The internal connection frame 352 may be disposed on the same plane as the first connection frame 332B and the second connection frame 342B.

The internal connection frame 352 has a through hole (symbol being omitted) that penetrates the internal connection frame 352 in the up-down direction. The through hole has a circular shape as viewed in the vertical direction. An upper end portion of the internal connection terminal 354 engages with the through hole by fitting engagement. The internal connection frame 352 and an electrode (not illustrated in the drawing) of the semiconductor element 320B are connected with each other by the internal connection terminal 354. The internal connection terminal 354 is fixed to the internal connection frame 352 by press fitting, for example.

### Connection Variations

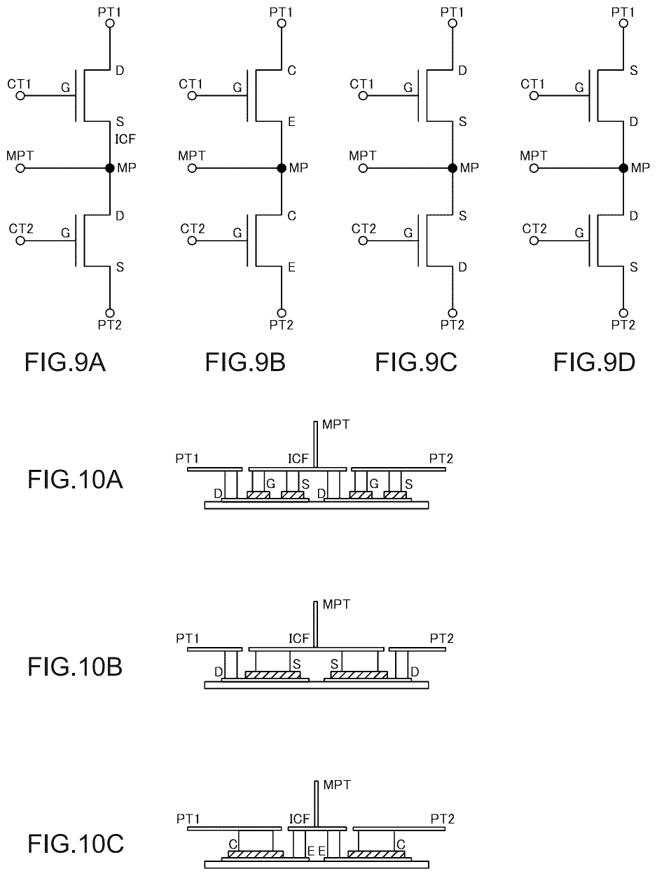

Hereinafter, an equivalent circuit and the cross-sectional structure in a case where the semiconductor element is a MOS transistor are described with reference to FIG. 9A to FIG. 9D and FIG. 10A to FIG. 10C. FIG. 9A is a view illustrating an equivalent circuit of the semiconductor elements 320A, 320B that constitute the electronic module 300, and FIG. 10A is view illustrating a cross-sectional structure of an electronic module corresponding to an equivalent circuit illustrated in FIG. 9A.

As illustrated in FIG. 9A and FIG. 10A, using the semiconductor 320B as a first MOS transistor (an upper-side transistor in FIG. 9A) and using the second semiconductor element 320A as a second MOS transistor (a lower-side transistor in FIG. 9B), the first MOS transistor and the second MOS transistor are connected to each other via a connection point (hereinafter, referred to as “node”) MP between an internal connection frame ICF and an intermediate point power terminal MPT (corresponding to 360 in FIG. 8) in series. Further, a drain electrode of first MOS transistor is connected to a first power terminal PT1 (corresponding to 340 in FIG. 8), a source electrode S of the first MOS transistor is connected to a drain electrode D of the second MOS transistor, and a source electrode S of the second MOS transistor is connected to a second power terminal PT2 (corresponding to 330 in FIG. 4).

Further, a source electrode S of the first MOS transistor is connected to the intermediate point power terminal MPT (corresponding to 360 in FIG. 4) via the internal connection frame ICF, and a gate electrode G of the first MOS transistor is connected to the control terminal (382 in FIG. 8) CT1. A gate electrode G of the second MOS transistor is connected to the control terminal (372 in FIG. 8) CT2.

In the above-mentioned configuration, the semiconductor element 320B on an upper side (the upper-side transistor) and semiconductor element 320A on a lower side (the lower-side transistor) are connected to each other in a forward direction (the source electrode S of the upper-side transistor being connected to the drain electrode D of the lower-side transistor). However, as a modification, as illustrated in FIG. 9C and FIG. 10B, the polarities of the semiconductor element 320A on the lower side may be reversed such that the source electrode S of the semiconductor element 320B on the upper side is connected to the source electrode S of the semiconductor element 320A on the lower side. Further, as another modification, as illustrated in FIG. 9D, the polarities of the semiconductor element 320B on the upper side may be reversed such that the drain electrode D of the semiconductor element 320B on the upper side is connected to the drain electrode D of the semiconductor element 320A on the lower side. The control terminals CT1, CT2 in FIG. 9A to FIG. 9D are input/output nodes for control signals.

Next, in the configuration illustrated in FIG. 9C and FIG. 10B, an equivalent circuit and a cross-sectional structure in a case where the MOS transistor is exchanged with an IGBT is illustrated in FIG. 9B and FIG. 10C. However, the configuration of the variation is equal to the configuration of the embodiment except for the point that the above-mentioned transistor is changed to an IGBT and hence, the explanation of the equivalent circuit and the cross-sectional structure of the modification is omitted. The same goes for the connection modes (the equivalent circuit and the cross section) other than the illustrated mode.

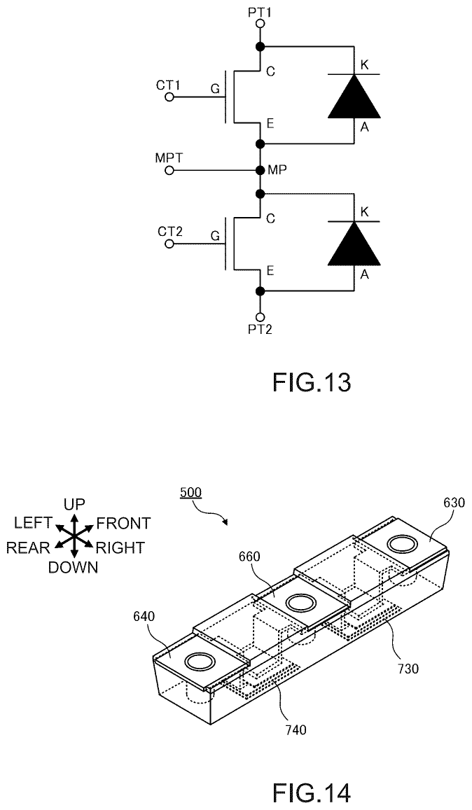

Next, an equivalent circuit in a case where the semiconductor element is an IGBT and a Schottky barrier diode (referred to as “SBD” hereinafter) is described with reference to FIG. 13. FIG. 13 illustrates the equivalent circuit where the number of the semiconductor elements that constitute the electric module 300 is four.

As illustrated in FIG. 13, a first IGBT (an upper-side IGBT in FIG. 13) and a first SBD (an upper-side SBD in FIG. 13) are connected in parallel, and a gate electrode G of the first IGBT is connected to a control terminal CT1. The first IGBT and a second IGBT (a lower-side IGBTs in FIG. 13) are connected in series via a node MP between an inner connection frame ICF and an intermediate point power terminal (corresponding to 360 in FIG. 8). Further, a second IGBT and a second SBD (a lower-side SBD in FIG. 13) are connected in parallel, and an emitter electrode E of the second IGBT is connected to a second power terminal PT2 (corresponding to 340 in FIG. 8). Further, an emitter electrode E of the first IGBT is connected to the intermediate point power terminal MPT (corresponding to 360 in FIG. 8) via a node MP. A gate electrode G of the first IGBT is connected to a control terminal (a pin terminal not illustrated in FIG. 8) CT1. Further, the gate electrode G of the second IGBT is connected to the control terminal CT2.

### Advantageous Effects Acquired by Second Embodiment

In this manner, the electronic module 300 according to the second embodiment differs from the electronic module 100 according to the first embodiment with respect to the point that the transistor is used in place of the diode as the semiconductor element. However, in the same manner as the electronic module 100 that includes two semiconductor elements, a contact area of two semiconductor elements with the internal connection frame 352 of the intermediate point power terminal can be made small and, at the same time, a package can be made short. Accordingly, it is possible to provide an electronic module where inductance and wiring resistance are reduced.

Further, as viewed in a plan view, the elongated hole extends along the direction that is orthogonal to the line that connects the first semiconductor element 320A and the second semiconductor element 320B in the region sandwiched between the other electrode of the first semiconductor element 320A and the other electrode of the second semiconductor element 320B. Accordingly, by extending the elongated hole in the direction orthogonal to the line that connects two semiconductor elements, a space can be formed in regions in the longitudinal direction of the internal connection frame 352 that constitutes the electronic module 300 and hence, the degree of freedom in packaging (designing of a package) and wiring designing can be enhanced.

Further, it is preferred that the first power terminal 330, the second power terminal 340 and the internal connection frame 352 are derived from the same lead frame. Accordingly, wiring lengths of connection wirings relating to the first power terminal 330, the second power terminal 340 and the internal connection frame 352 can be made short and hence, it is possible to provide the electronic module where inductance and wiring resistance can be reduced.

Further, the first semiconductor element 320A further includes the first control electrode (gate electrode), and the second semiconductor element 320B further includes the second control electrode (gate electrode), and the electronic module 300 further includes: a control terminal CT2 connected to a first control electrode of the first semiconductor element 320A; and a control terminal CT1 connected to a second control electrode of the second semiconductor element 320B. Accordingly, wiring lengths of connection lines that are connected to the first power terminal 330, the second power terminal 340 and the internal connection frame 352 can be shortened and hence, it is possible to provide an electronic module having a half bridge structure where inductance and wiring resistance are reduced.

### Third Embodiment

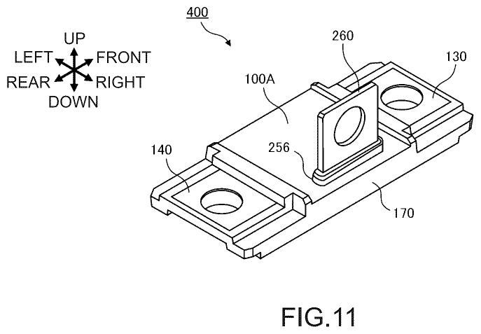

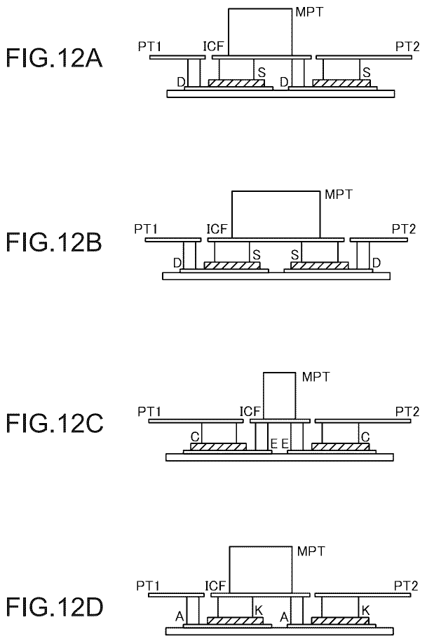

Hereinafter, an electronic module according to a third embodiment of the present invention is described with reference to FIG. 11 and FIG. 12A to FIG. 12D. The third embodiment has substantially the same configuration as the above-mentioned first embodiment except for the following points. Accordingly, only the different points are described, and the description of the substantially the same portions is omitted. Further, symbols other than symbols that indicate the different points are not necessary in discrimination and hence, the substantially the same symbols as used in the first embodiment are used in the third embodiment.

Further, as viewed in a plan view, an elongated hole 256 extends along the direction parallel to a line that connects a first semiconductor element 118 and a second semiconductor element 120 to each other in regions that do not overlap with the other electrode of the first semiconductor element 118 and the other electrode of the second semiconductor element 120. In this embodiment, in a case where the electronic module 400 according to the second embodiment is a diode module, a cross section structure of the electronic module is a structure illustrated in FIG. 12D. In a case where both two semiconductor elements in the electronic module 400 are formed of an MOS transistor

Respectively, the cross-sectional structure of the electronic module are cross-sectional structures illustrated in FIG. 12A and FIG. 12B. In a case where both two semiconductor elements in the electronic module 400 are formed of an IGBT respectively, the cross section structure of the electronic module are cross section structures illustrated in FIG. 12C.

### Advantageous Effects Acquired by Third Embodiment

The elongated hole 256 extends along the direction parallel to the line that connects the first semiconductor element 118 and the second conductor element 120 to each other in regions that do not overlap with the other electrode out of the first electrode and the second electrode of the first semiconductor element 118 and the other electrode out of the third electrode and the fourth electrode of the second semiconductor element 120. With such a configuration, a space is formed in the regions of the electronic module (particularly, the internal connection frame) in the left-right direction and hence, the degree of freedom in packaging (designing of a package) and wiring designing can be enhanced.

1. An electronic module comprising:
a first semiconductor element that includes two electrodes consisting of a first electrode and a second electrode;
a second semiconductor element that includes two electrodes consisting of a third electrode and a fourth electrode ;
a first power terminal having a flat plate shape that is connected to either one electrode out of the first electrode and the second electrode;
a second power terminal having a flat plate shape that is connected to either one electrode out of the third electrode and the fourth electrode; and
an intermediate point power terminal having a flat plate shape that is connected to an other electrode out of the first electrode and the second electrode and an other electrode out of the third electrode and the fourth electrode, wherein
the electronic module further comprises an internal connection frame having a flat plate shape that connects the other electrode out of the first electrode and the second electrode and the other electrode out of the third electrode and the fourth electrode to each other, the internal connection frame having an elongated hole provided for fitting the intermediate point power terminal therein by press fitting, and
the intermediate point power terminal is erected in a perpendicular direction by being fitted into the elongated hole of the internal connection frame by press fitting.

2. The electronic module according to claim 1, wherein, as viewed in a plan view, the elongated hole extends in a direction that is orthogonal to a line that connects the first semiconductor element and the second semiconductor element, in a region that is sandwiched between the other electrode out of the first electrode and the second electrode and the other electrode out of the third electrode and the fourth electrode.

3. The electronic module according to claim 1, wherein, as viewed in a plan view, the elongated hole extends in a direction that is parallel to a line that connects the first semiconductor element and the second semiconductor element, in a region that does not overlap with the other electrode out of the first electrode and the second electrode and the other electrode out of the third electrode and the fourth electrode.

4. The electronic module according to claim 1, wherein the first power terminal, the second power terminal and the internal connection frame are derived from a same lead frame.

5. The electronic module according to claim 1, wherein
the first semiconductor element further includes a first control electrode,
the second semiconductor element further includes a second control electrode, and
the electronic module further comprises:
a first control terminal that is connected to the first control electrode of the first semiconductor element, and
a second control terminal that is connected to the second control electrode of the second semiconductor element thus forming a half bridge structure.
